(19) United States
(12) Patent Application Publication
(10) Pub. No.: US 2022/0275275 A1
(43) Pub. Date: Sep. 1, 2022

(54) STABLE PHOSPHOR CONVERTED LED AND SYSTEM USING THE SAME

(71) Applicant: CURRENT LIGHTING SOLUTION, LLC, East Cleveland, OH (US)

(72) Inventors: Jenna Marie Baldesare, East Cleveland, OH (US); Fangming Du, East Cleveland, OH (US); Ashfaqul Islam Chowdhury, East Cleveland, OH (US); Rick Dean Dureiko, East Cleveland, OH (US); Clark Nelson, East Cleveland, OH (US)

(21) Appl. No.: 17/631,037

(22) PCT Filed: Jul. 30, 2020
(86) PCT No.: PCT/US2020/044154

§ 371 Date: Jan. 28, 2022

Related U.S. Application Data
(60) Provisional application No. 62/880,629, filed on Jul. 30, 2019.
(60) Provisional application No. 62/881,034, filed on Jul. 31, 2019.

(51) Int. Cl. C09K 11/61; C09K 11/02; H01L 33/50

(52) U.S. Cl. CPC C09K 11/617; C09K 11/02; H01L 33/502; H01L 2933/0041

(57) ABSTRACT

According to some embodiments, an apparatus and method are provided comprising: an enclosure defining a cavity within the enclosure, the cavity comprising a depth dimension; at least one LED chip; a layer comprising a blend of an encapsulant material and phosphor composition, the layer overlaying the at least one LED chip and disposed within the cavity; the phosphor composition comprising a yellow-green phosphor and a Mn⁴⁺ doped complex fluoride phosphor of formula I, Aₓ[MF_{y}]:Mn⁴⁺ (I) where A is Li, Na, K, Rb, Cs, NR₄ or a combination thereof; M is Si, Ge, Sn, Ti, Zr, Al, Ga, In, Sc, Hf, Y, La, Nb, Ta, Bi, Gd, or a combination thereof; R is H, lower alkyl, or a combination thereof; x is the absolute value of the charge of the [Mf_{y}] ion; and y is 5, 6, or 7; wherein the Mn⁴⁺ doped complex fluoride phosphor of formula I comprises a d50 particle size of from about 1 micrometers to about 10 micrometers, and the LED lighting apparatus, when activated, emits visible light comprising a correlated color temperature (CCT) of from about 2500 K to about 3700 K. Numerous other aspects are provided.

### CROSS REFERENCE TO RELATED APPLICATIONS

This application claims benefit to and priority of U.S. Provisional Patent Application Ser. No. 62/881,034, filed Jul. 31, 20219, entitled “STABLE PHOSPHOR CONVERTED LED AND SYSTEM USING THE SAME”, the contents of which are hereby incorporated herein by reference in their entirety for all purposes.

This application claims benefit to and priority of U.S. Provisional Patent Application Ser. No. 62/880,629 filed Jul. 30, 2020, entitled “STABLE PHOSPHOR CONVERTED LED AND SYSTEM USING THE SAME”, the contents of which are hereby incorporated herein by reference in their entirety for all purposes.

This application claims benefit to and priority of PCT International Patent Application Serial No. PCT/US2020/44154 filed Jul. 30, 2020, entitled “STABLE PHOSPHOR CONVERTED LED AND SYSTEM USING THE SAME”, the contents of which are hereby incorporated herein by reference in their entirety for all purposes.

### BACKGROUND

The LED package industry values narrow red emission from phosphor-converted LED packages. It is challenging to obtain enhanced red light down-conversion from a given flux level of blue light from an LED light source, while improving damage resistance to high optical flux. There is always demand for improved phosphor performance (e.g., increased conversion efficiency) and higher phosphor reliability (e.g., lower material damage at higher LED flux levels) when employed in LED packages.

It would be desirable to provide systems and methods for improved phosphor-converted LED packages.

### SUMMARY

According to some embodiments, an LED lighting apparatus is provided comprising an enclosure defining a cavity within the enclosure, the cavity comprising a depth dimension; at least one LED chip; a layer comprising a blend of an encapsulant material and phosphor composition, the layer overlaying the at least one LED chip and disposed within the cavity; the phosphor composition comprising a yellow-green phosphor and a Mn⁴⁺ doped complex fluoride phosphor of formula I, Aₓ[Mf_{y}]:Mn⁴⁺ (I) where A is Li, Na, K, Rb, Cs, NR₄ or a combination thereof; M is Si, Ge, Sn, Ti, Zr, Al, Ga, In, Sc, Hf, Y, La, Nb, Ta, Bi, Gd, or a combination thereof; R is H, lower alkyl, or a combination thereof; x is the absolute value of the charge of the [MF_{y}] ion; and y is 5, 6, or 7; wherein the M⁴⁺ doped complex fluoride phosphor of formula I comprises a d50 particle size of from about 1 micrometers to about 10 micrometers, and the LED lighting apparatus, when activated, emits visible light comprising a correlated color temperature (CCT) of from about 2500 K to about 3700 K.

According to embodiments, a method is provided, comprising: receiving phosphor pre-cursor for a phosphor composition comprising a yellow-green phosphor and a Mn⁴⁺ doped complex fluoride phosphor of formula I, Aₓ[MF_{y}]:Mn⁴⁺ (I) where A is Li, Na, K, Rb, Cs, NR₄ or a combination thereof; M is Si, Ge, Sn, Ti, Zr, Al, Ga, In, Sc, Hf, Y, La, Nb, Ta, Bi, Gd, or a combination thereof; R is H, lower alkyl, or a combination thereof; x is the absolute value of the charge of the [MF_{y}] ion; and y is 5, 6, or 7; generating the phosphor pre-cursor for the phosphor composition of formula I having a d50 particle size of from about 1 micrometer to about 10 micrometers; generating the phosphor composition of formula I from the generated phosphor pre-cursor having the d50 particle size of from about 1 micrometer to about 10 micrometers; constructing an LED lighting apparatus with the generated phosphor composition; and in a case that the constructed LED lighting apparatus is activated, emitting visible light comprising a CCT from about 2500K to about 3700K.

The disclosure relates generally to red emission from phosphor converted LEDs. More particularly, the disclosure relates to manganese-activated luminescent materials which are excited by blue or violet light (such as blue light emitted by LED chips) and emit in the red region of the visible spectrum; and LED packages that include such materials. Some technical effects of some embodiments disclosed herein are an improved lighting device that exhibits improved performance and reliability of an Mn-activated red phosphor, as compared to a conventional system at a same given doping level of Mn⁴⁺.

With this and other advantages and features that will become hereinafter apparent, a more complete understanding of the nature of the invention can be obtained by referring to the following detailed description and to the drawings appended hereto.

### BRIEF DESCRIPTION OF THE DRAWINGS

FIG. 1A is a scanning electron microscopy (SEM) image of a conventional large particle size PFS.

FIG. 1B is a SEM image of a small particle size PFS according to some embodiments.

FIG. 2 is a diagram comparing conventional large particle size PFS to small particle size PFS according to some embodiments.

FIG. 3 is a process according to some embodiments.

FIG. 4 is a first non-exhaustive example of a lighting device according to some embodiments.

FIG. 5 is a second non-exhaustive example of a lighting device according to some embodiments.

FIG. 6 is a third non-exhaustive example of a lighting device according to some embodiments.

FIG. 7 is a fourth non-exhaustive example of a lighting device according to some embodiments.

FIG. 8 is a fourth non-exhaustive example of a lighting device according to some embodiments

### DETAILED DESCRIPTION

In the following detailed description, numerous specific details are set forth in order to provide a thorough understanding of embodiments. However, it will be understood by those of ordinary skill in the art that the embodiments may be practiced without these specific details. In other instances, well-known methods, procedures, components and circuits have not been described in detail so as not to obscure the embodiments.

One or more specific embodiments of the present invention will be described below. In an effort to provide a concise description of these embodiments, all features of an actual implementation may not be described in the specification. It should be appreciated that in the development of any such actual implementation, as in any engineering or design project, numerous implementation-specific decisions may be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

Approximating language, as used herein throughout the specification and claims, may be applied to modify any quantitative representation that could permissibly vary without resulting in a change in the basic function to which it is related. Accordingly, a value modified by a term or terms, such as “about,” is not limited to the precise value specified. In some instances, the approximating language may correspond to the precision of an instrument for measuring the value. For example, the term, “about” used in context of a wavelength value may refer to a value of a wavelength up to ±20 nm of the specified wavelength value, and is applicable to all incidences of the term “about” as used herein for a wavelength value throughout the specification.

As used herein, the term “phosphor” or “phosphor material” or “phosphor composition” may be used to denote both a single phosphor composition as well as a blend of two or more phosphor compositions. As used herein, the term “lamp” or “lighting device” or “lighting system” refers to any source of visible and/or ultraviolet light which may be generated by at least one light emitting element producing a light emission when energized (for example, a phosphor material) by a light emitting diode.

As described above, the present disclosure relates to manganese-activated luminescent materials which are excited by blue or violet light (such as blue light emitted by LED chips) and emit in the red region of the visible spectrum; and LED packages that include such materials. Such luminescent materials may be alternatively referred to in this disclosure as Mn-activated red phosphors, Mn⁴⁺ activators or Mn⁴⁺ doped complex fluoride phosphor of formula I, where formula I is as follows:

Aₓ[MF_{y}]:Mn⁴⁺ (I)

where A is Li, Na, K, Rb, Cs, NR₄ or a combination thereof; M is Si, Ge, Sn, Ti, Zr, Al, Ga, In, Sc, Hf, Y, La, Nb, Ta, Bi, Gd, or a combination thereof; R is H, lower alkyl, or a combination thereof; x is the absolute value of the charge of the [Mf_{y}] ion; and y is 5, 6, or 7. A “lower” alkyl is usually a hydrocarbyl group of from 1 to about 4 carbons.

One non-exhaustive example of an Mn-activated red phosphor is PFS (K₂SiF₆:Mn⁴⁺) phosphor. This substance is available for LED manufacturers to incorporate into LED packages.

The present disclosure describes systems that employ Mn-activated red phosphor in an LED package, which exhibits improved performance and reliability of the red phosphor, as compared to a conventional system at a same given doping level of Mn⁴⁺ activator. Embodiments may exploit red phosphor particles that are significantly smaller (˜5 micrometers) compared to typical Mn-activated red phosphor particle size (˜30 micrometers). Incorporation of a smaller particle-size Mn-activated red phosphor into a resin that encapsulates LED packages may result in the resultant LED package showing an increased red phosphor conversion efficiency, as well as decreased susceptibility to damage from high optical flux.

As used herein, a characteristic parameter of the LED package called “red phosphor conversion efficiency” or sometimes alternatively “red-blue power ratio” is often used. Under either nomenclature, it may refer to a ratio of the integrated power (measured in units of radiated Watts, for example) under the emission curve in the red region for resin-encapsulated red phosphor under blue-LED excitation, relative to the power of the blue light excitation, at constant content of Mn-activator in its host matrix. As one non-limiting example, blue power may be measured by integrating the radiated power from the package in the range of from 400 nm to 477 nm, whereas red power may be measured by integrating the radiated power from the package in the range of from 550 nm to 700 nm. (It is noted, however, that the precise wavelength ranges of integration are chosen to ensure all measured red and blue power is considered in the calculation. These specific ranges are dependent on source and emission spectra, as would be well understood by the person having ordinary skill in the art). For the case of the Mn-activated red phosphor being K₂SiF₆:Mn⁴⁺ (i.e., PFS), the LED package of one or more embodiments that uses resin-encapsulated small particle size PFS may exhibit an increased red phosphor conversion efficiency, when compared to an identical LED package that employs PFS at larger particle size but same molar content of Mn⁴⁺ relative to K₂SiF₆. Other host matrices are possible (e.g., K₂TiF₆ for K₂TiF₆:Mn⁴⁺ red phosphor, etc.), of course, as would be suggested by the scope of Formula I above.

When Mn-activated red phosphor at a specified small particle size is contained in the resin encapsulating an LED package, a more robust red-phosphor-containing LED package may result, that may operate more efficiently and at higher flux levels than conventional LED packages including Mn-activated red phosphor at larger particle sizes. The performance improvement may be most marked when phosphor particle size is reduced from ˜30 μm to ˜5 μm, although other values are possible. As aforementioned, LED packages made according to the present disclosure may exhibit significantly more red light being converted when pumped by blue LEDs. Without being limited by theory, it is believed that (due to the small particle size of the Mn-activated red phosphor), this red phosphor may remain better dispersed in resin encapsulant (e.g., the industry standard silicone epoxies) that are commonly used in white LED manufacturing. Such enhanced dispersion may enable less damage to the red phosphor at higher optical flux. Note that similar results may be obtained with other types of encapsulant materials, such as silicone resin, epoxy resins, acrylate resins, or combinations thereof; or the like.

The systems of the present disclosure may be used to build warm-white LED packages, cool-white LED packages, or any other suitable LED packages, having robust Mn-activated red phosphors, application in indoor or outdoor illumination, or displays.

Red Phosphor

By “red phosphor of the present disclosure” is meant the Mn-doped red phosphor of formula I. A non-exhaustive example of such red phosphor is PFS, K₂SiF₆:Mn.

Small Particle Sized Red Phosphor

A small particle size red phosphor of the present disclosure (with a particle size of 10 microns or less) may be prepared by any suitable method, such as by the wet milling system described in Beers, US patent publication 20160289553, hereby incorporated by reference in its entirety for all purposes, which shows attainment of red phosphor of Formula I, in a size range of from 1 to 30 microns. As described therein, a phosphor precursor is milled into particles followed by treating the milled particles to enhance performance and stability of a resulting manganese-doped red phosphor, where the resulting manganese-doped red phosphor results from further processing of the treated milled particles of the phosphor precursor. The phosphor precursor is milled (or ground) to reduce particle size for desired properties. Milling or grinding particles of the phosphor precursor of formula I can be carried out for a selected period of time with a rotational milling speed that depends, in part, on the size of the particles before milling, along with the desired size of the resulting particles after milling. Other methods are possible to achieve the small sized described by the present disclosure.

In some embodiments, before or after milling, the particles may be treated to enhance performance and stability of the resulting small particle size Mn-doped red phosphor. As part of the aforementioned enhanced performance and stability treatment, in one embodiment, the milled particles may be contacted with a fluorine-containing oxidizing agent in gaseous form at an elevated temperature. Other methods for enhancing performance and stability may be possible. In some embodiments (but not in others), the small particle size red phosphor of the present disclosure may have been subjected to a color-stabilization process, such as by annealing in a fluorine-containing oxidizing atmosphere at elevated temperatures, as disclosed in commonly-owned prior US patent publication 20150361335 and U.S. Pat. No. 9,698,314-B2, all of which are hereby incorporated by reference in their entirety for all purposes.

Particle Size Measurement

As used in this disclosure, particle size determination for Mn-doped red phosphor having a nominal diameter of about 10 microns or less, is performed via an image analysis. That is, laser light-scattering techniques are not ordinarily used for determination of particle sizes of Mn-doped red phosphor when the nominal diameter is about 10 microns or less. Instead, a microscopic imaging analysis is performed, usually using SEM (scanning electron microscopy). The person having ordinary skill in the art would understand how to employ scanning electron microscopy for determination of average particle sizes of primary, that is, non-agglomerated, particles. For example, a scanning electron microscopy image of a powder sample may be obtained at a magnification of 1500 times. This image may be subjected to a post processing, where image processing is applied to enhance particle edges and convert the image to a binary image. Then, particle statistics may be collected, and a volume-based particle size distribution report may be extracted, so as to arrive at a d50 particle size metric, where 50% of the particles in the sample are larger than the d50 value, and 50% of the particles in the sample are smaller than the d50 value. This is essentially the method defined in the present disclosure for discovery of particle size for PFS phosphor having nominal diameter of 10 microns or less. In general, distributions can be either normalized to total number of particles or total volume of particles. But, in order to be consistent with industry standard reporting (e.g. diffraction-based measurement system), volume based is reported here. In summary, an image is acquired, and at a given magnification, the average size of the primary particles is determined.

Stability to High Optical Flux

As noted, when used as part of a phosphor composition dispersed in a polymeric matrix, and when it comprises a suitably small particle size (i.e., 10 microns or less), the phosphor composition of the present disclosure may suffer less damage due to high optical flux. This is usually measured by laser damage based on exposure to a blue laser for a specified period of time. Laser damage is a proxy for accelerated aging or degradation that a phosphor composition may undergo upon prolonged exposure to blue LED light as part of an LED package, in use. By way of example, a conventional PFS phosphor of conventional size may ordinarily suffer a laser damage value of 2% after 24 hours exposure to the test blue laser light. This refers to a 2% degradation in phosphor emission light output after treatment by the laser for the specified period of time. However, the Mn-activated red phosphor having the specified small particle size of the present disclosure (i.e., 10 microns or less) (when dispersed in a polymeric encapsulating matrix and used in accordance with the claimed invention), may show a laser damage of merely half that of the conventional PFS phosphor.

The laser-damage accelerated degradation test may typically be performed according to the following general protocol: the small particle size phosphor composition is dispersed within an encapsulated polymeric resin and made into a tape format. Then a blue semiconductor laser is effectively positioned at the bottom of the tape analogous to the position that an LED chip would reside in, within an LED package. A laser diode emitting at 445 nm is coupled to an optical fiber with a collimator at its other end. The power output may be approximately 280 mW and the beam diameter at the sample may be 600 microns. This is equivalent to a flux of approximately 100 W/cm² on the sample surface. The spectral power distribution (SPD) spectrum (which is a combination of the scattered radiation from the laser and the emission from the excited phosphor) is collected with a 1 meter (diameter) integrating sphere and the data processed with spectrometer software. At intervals of two minutes, the integrated power from the laser and the phosphor emission are recorded over a period of about 24 hours by integrating the SPD from 400 nm to 500 nm and 550 nm to 700 nm respectively. The first 90 minutes of the measurement are discarded to avoid effects due to the thermal stabilization of the laser. The integrated power from the laser emission, as well as its peak position, is monitored to ensure that the laser remains stable (variations of less than 1%) during the experiment. For example, a 1 percent laser damage value refers to the percent decrease or decrement in red emission output after exposure to the given laser intensity for period of 24 hours.

Without being limited by theory, the reason why this small particle size PFS phosphor may suffer less laser damage, and thus less degradation, over time is because it is distributed in a more favorable configuration in the encapsulant resin, relative to the conventional PFS blend suspended in encapsulant resin.

Phosphor Compositions

Embodiments of the invention are directed to an LED package comprising a blue semiconductor light source in radiational coupling to a resin encapsulant comprising a blend of phosphors or a phosphor composition. Radiationally coupled means that the elements are associated with each other so radiation from one is transmitted to the other. The phosphor composition, in certain embodiments, comprises the noted small particle size Mn-doped red phosphor (e.g., PFS) and yellow green phosphor such as YAG (yttrium aluminum garnet) or LAG (lanthanum aluminum garnet), or any effective yellow-green phosphor than can provide the BSY-effect (blue-shifted yellow), to provide light that appears white. In some preferred embodiments, the d50 value for particle size of Mn-doped red phosphor is about or substantially 5 micrometers in diameter. The phosphor composition within the LED packages of embodiments of this disclosure, may also comprise one or more of: a further red phosphor or quantum dot (narrow or broad), a further yellow phosphor or quantum dot, a further green phosphor (e.g., a beta sialon) or quantum dot, a blue phosphor or quantum dot, or an orange phosphor or quantum dot. It may also comprise one or more luminescent quantum dots of these emission colors (quantum dots being luminescent inorganic semiconductor particles of specified size, generally in the nanometer-scale dimension). In some embodiments, the yellow-green phosphor may be replaced in part or in whole by a beta-sialon phosphor, such as a europium (II)-doped β-SiAlON phosphor. In some embodiments, the further red phosphor may comprise a red europium-doped silicon nitride phosphor (e.g., SCASN or CASN).

Particle Size Ranges: Choice and Effect

Exemplary embodiments for particle size, for the small particle size Mn-doped red phosphor of the present disclosure, have included the use of 5 micron sized particles (d50) and 10 micron sized particles. For an increased particle size, there is a monotonic decrease in red to blue power emission ratio. At around 20 microns in size for Mn-doped red phosphor, the red to blue power emission ratio is not much different than the value observed at the conventional 30 microns size particle. In accordance with embodiments of the disclosure, the d50 particle size may be in a range of from about 1 micrometer to about 10 micrometers. More specifically, the d50 particle size may range in an amount of from about 5 microns to about 10 microns. Below about 1 micron, the difficulty in handling such small particle size manganese doped phosphor may become too great. Above about 20 microns, the enhanced red blue power emission ratio relative to the conventional 30 micron particle size manganese doped phosphor, is lessened or nonexistent.

Note that the red-to-blue ratio may also be deduced from the color point, more specifically, the chromaticity (ccx, ccy) values from the 1931 CIE chromaticity diagram. By comparing the ccx value of the light emitted by an LED package using the small particle size PFS with a like LED package that has the conventional larger particle size, the person of ordinary skill may also deduce the enhancement in the red-blue ratio.

By employing Mn-doped red phosphor in the specified small particle size range disclosed in one or more embodiments, an LED package may be provided (e.g., constructed or attained) that may emit light with a correlated color temperature (CCT) in the range of from about 2500 Kelvin to about 3500 Kelvin (such as about 3000 K). Due to the small particle size, an enhanced red output may be achieved at a lower weight percent of phosphor loading of Mn-doped red phosphor. As a result, the desired CCT may be attained even in a typical depth for the cavity of an LED package, using a relatively lower weight percent of Mn-doped red phosphor. It is noted that while it may be possible to achieve CCT of from about 2500-3500 K without using small particle size Mn-doped red phosphor, this would require an excessively large phosphor loading, or a very high level of Mn dopant. The inventors have ascertained that excessively high weight percent of manganese doped red phosphor in an encapsulated blend may lead to reliability problems. Therefore, it may be advantageous to keep the loading level of phosphor relatively low. But even within the constraint of low phosphor-loading, a high red output may help achieve color temperature correlated color temperature in the 2500 Kelvin to 3500 Kelvin range. The small particle size manganese doped red phosphor of one or more embodiments is a solution to this dilemma, as it may emit the requisite amount of red from its luminescence, even when present at an acceptable phosphor loading level.

As a non-exhaustive example, phosphor loading levels of one or more embodiments may be below about 50 weight percent; that is, for each 100 grams of combined mass of encapsulant resin and total phosphor, there may be less than about 50 grams of total phosphor. Other suitable amounts may be used. Because of the higher red output for the small particle size phosphor of one or more embodiments, LED packages may be constructed at moderate color temperature, such as 2500 K to 3500 K, with high reliability.

In some embodiments, LED packages of the present disclosure may be configured as a warm white LED package (CCT of 2500K-3500 K) in a mid-power configuration, achieving L90 greater than 36000 hours (i.e., 90% of lumen maintenance at 36000 h). In other embodiments, the LED packages of the present disclosure may be configured as a cool white LED package (CCT of 3500 K to 5000K) in mid-power configuration, achieving L90 greater than 36000 hrs at >100 mA for ca. 1 W mid power LED package.

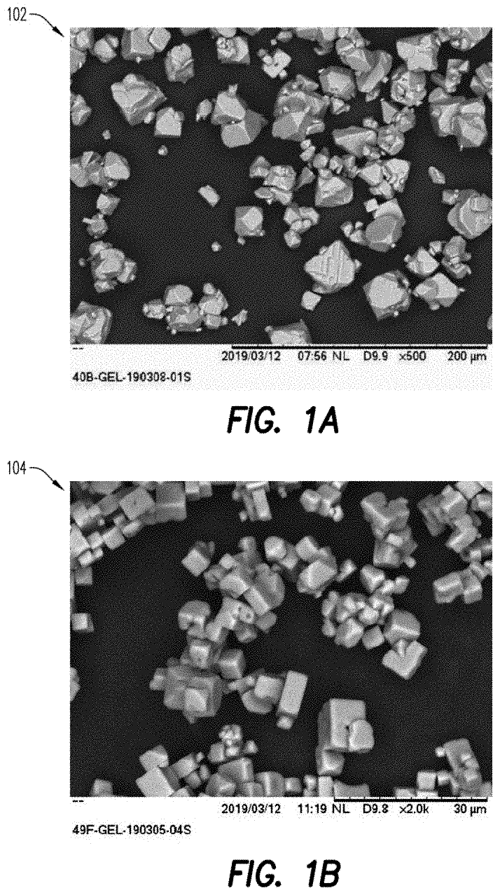

Turning to FIGS. 1A and 1B, SEM images of representative samples of large particle size PFS 102 (FIG. 1A) and small particle size PFS 104 (FIG. 1B), respectively, are provided. In FIG. 1A, the large particle size (ca. 28 micrometers d50 particle size) is typical of many conventional PFS phosphors. In this example, the PFS of FIG. 1A had a Mn-doping level of 1.5 atom %, and an initial red-blue ratio (at 100 W/cm2) of 3.6, as well as laser damage level of 2%. In contrast, FIG. 1B is typical of a small-particle-size PFS of the present disclosure. It has particle size of 5 micrometers (d50), and a Mn-dopant level of 1.4%, yet when incorporated into silicone resin and encapsulated in an LED package, exhibited initial red-to-blue ratio of around 6.0 and suffered laser damage of only 1.0%.

### Exemplary Embodiments

### EXAMPLE 1

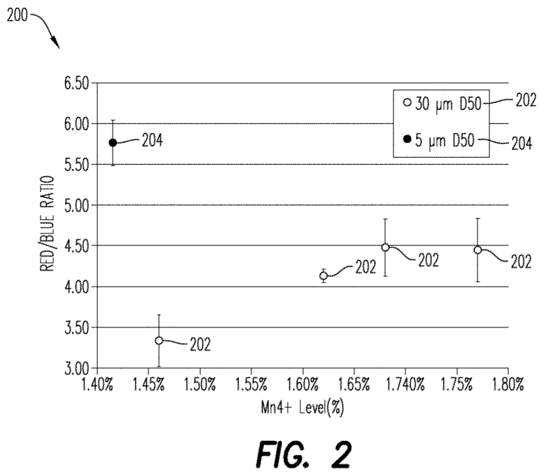

FIG. 2 describes the experimental results 200 surrounding the use of 5 micron particle size PFS phosphor of the present disclosure versus conventional 30 micron particle size PFS phosphor, at various manganese-dopant levels in PFS. The filled points 202 in FIG. 2 refer to 30 micron PFS phosphor encapsulated in a silicone resin, and made a part of an LED package. The various filled points 202 are placed at various content levels for tetravalent manganese in the doped PFS phosphor. For example, the far bottom left point 202 is for 30 micron PFS phosphor at a manganese doping level of about 1.46% (relative to central Si atom in the host). Use of such phosphor exhibits a red/blue power ratio of under 3.5. Even upon an increase in manganese level to about 1.77% manganese, the red/blue ratio cannot be increased above about 4.5. However, as shown by the empty point 204 in the upper left corner of Table I, use of 5 micron particle size (average d50) of PFS phosphor in a dispersion in silicone encapsulant, can allow the attainment of a red/blue power ratio of greater than 5.5. Note that reference to manganese content as determined by x-ray fluorescence spectroscopy refers to the determination of atom percentage of the manganese dopant in the Mn-doped red phosphor.

### EXAMPLE 2

Table I below depicts experimental results for PFS phosphor at various nominal particle sizes.

TABLE I

| | | LD IRP @ | | | |
|---|---|---|---|---|---|
| Nominal | Mn % | (100 | Blue Power | Red Power | |
| PSD | (XRF) | W/cm\hat{ }2) | (W) | (W) | Red/Blue |
| 5 | 1.54% | 1.0% | 0.116 | 0.724 | 6.25 |
| 20 | 1.49% | 1.7% | 0.141 | 0.660 | 4.71 |
| 30 | 1.47% | 1.7% | 0.166 | 0.626 | 3.77 |
| 20 | 1.48% | 0.9% | 0.139 | 0.621 | 4.47 |
| 30 | 1.47% | 1.6% | 0.172 | 0.597 | 3.48 |
| 40 | 1.48% | 3.3% | 0.191 | 0.583 | 3.07 |
| 30 | 1.47% | 2.0% | 0.169 | 0.604 | 3.56 |
| 40 | 1.49% | 4.4% | 0.172 | 0.595 | 3.49 |
| 50 | 1.49% | 3.9% | 0.181 | 0.582 | 3.22 |
| 10 | | 1.3% | 0.128 | 0.619 | 4.84 |

The particle size measured as d50 particle size is given in the first column of Table I. In successive columns of the table, LD (laser damage parameters) is given, and in the far right column of the table, red/blue power ratio is given. When the nominal particle size diameter is 30 microns (which is a conventional particle size, not part of this invention), with a manganese atom percentage as measured by X Ray fluorescence of 1.47%, then the values of laser damage and red/blue ratio are unacceptable. In one run, the laser damage found was 1.6% (after irradiation with 100 Watts per square centimeter blue power). For this same sample, red/blue power ratio was 3.48. In another run, the laser damage was 2.0% measured in the same way; and the red blue ratio was 3.56. However, upon use of 5 micron PFS phosphor at similar manganese content (namely, 1.54%), then the laser damage was a mere 1.0%, and the red blue ratio enhanced to 6.25.

Note that the LED packages are LED lighting apparatuses of the present disclosure and may be employed in general illumination applications such as lamps for general illumination. However, it may also be possible to use the LED packages of the present disclosure in signage, backlights for displays, outdoor lighting, indoor fixtures, signaling, televisions, mobile devices, decorative lighting, or any other application in which LED packages may be suitably employed.

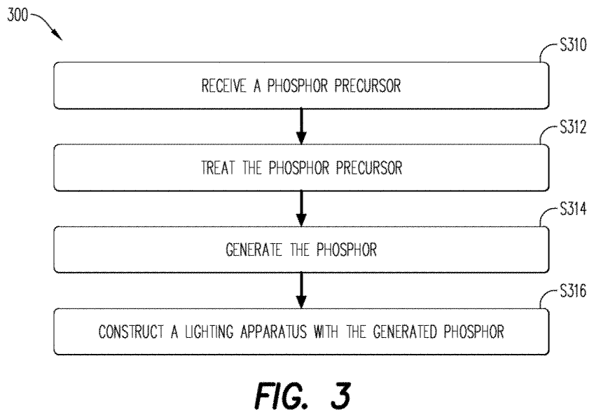

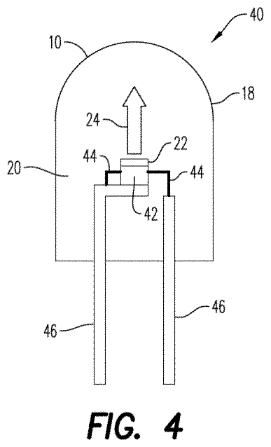

Turning to FIGS. 3-7, examples of a lighting device 40 (FIGS. 4, 5, 6, 7) and examples of operation according to some embodiments are provided. In particular, FIG. 3 provides a flow diagram of a process 300, according to some embodiments. Process 300, and any other process described herein, may be performed using any suitable combination of hardware (e.g., circuit(s)), software or manual means. Examples of these processes will be described below with respect to embodiments of the system, but embodiments are not limited thereto. The flow charts described herein do not imply a fixed order to the steps, and embodiments of the present invention may be practiced in any order that is practicable.

In particular, turning to FIG. 3, a process for preparing a small particle size phosphor composition for use in a lighting apparatus 40 is provided. Initially, at S310, a phosphor pre-cursor is received. Then in S312, the phosphor pre-cursor is treated. In one or more embodiments, the phosphor pre-cursor may be treated to obtain a desired particle size. As described above, as a non-exhaustive example, the treatment may include milling the phosphor pre-cursor. In some embodiments, the particle size may be measured via scanning electron microscopy (SEM), for example, to determine whether the particle size after milling is the desired size (i.e., small particle size). Additionally, in one or more embodiments, the phosphor pre-cursor may be treated, before or after milling, to enhance performance and stability of the resulting generated small particle size red phosphor. As a non-exhaustive example, the phosphor pre-cursor may be contacted with the fluorine-containing oxidizing agent in a gaseous form at an elevated temperature; may be subjected to a color-stabilization process, such as by annealing in a fluorine-containing oxidizing atmosphere at elevated temperatures. Next, in S314, the phosphor is generated using the phosphor pre-cursor via any suitable phosphor generation process. The generated small particle red phosphor is then used in the construction of a lighting apparatus in S316. In one or more embodiments, the lighting apparatus, when activated, emits visible light comprising a CCT of from about 2500K to about 3700K. In embodiments, the lighting apparatus, when activated, emits visible light comprising a CCT of from about 2500K to 3500K.

Turning to FIG. 4, a lighting device 40 including a phosphor material radiationally coupled to a light source is provided, according to some embodiments of the present disclosure. As used herein, the terms “lighting apparatus,” “lighting device,” “light emitting assembly” and “lamp,” may be used interchangeably. The lighting device 40 includes an enclosure (e.g., envelope/shell/encapsulant 18) defining a cavity 10 within the enclosure 18, the cavity 10 comprising a depth dimension of about 200 microns to about 800 microns. The lighting device 40 includes a semiconductor radiation source, shown as a light emitting diode (LED) chip 42 and leads 44 electrically attached to the LED chip 42. The leads 44 may be thin wires supported by a thicker lead frame 46 or the leads may be self-supported electrodes and the lead frame may be omitted. The leads 44 provide current to LED chip 42 and thus cause it to emit radiation. While the examples in FIGS. 4-6 show one LED chip, other suitable numbers of LED chips may be included in the lighting devices 40.

The lighting device 40 may include any semiconductor blue or ultraviolet light source that is capable of producing white light when its emitted radiation is directed onto a small particle size red phosphor of the present disclosure. In one embodiment, the semiconductor light source is a blue emitting LED. The LED chip 42 may comprise a semiconductor diode based on any suitable III-V, II-VI, or IV-IV semiconductor layers and having an emission wavelength of about 250 to 550 nm. The LED chip 42 may be, for example based on a nitride compound semiconductor of formula InᵢGaⱼAlₖN (where 0 is less than or equal to i; 0 is less than or equal to j; 0 is less than or equal to k and i+j+k=l) having an emission wavelength greater than about 250 nm and less than about 550 nm. More particularly, the LED chip 42 may be a near-UV or blue emitting LED having a peak emission wavelength from about 350 nm to about 500 nm. The radiation source is described herein as an LED for convenience. However, as used herein, the term is meant to encompass all semiconductor radiation sources including, e.g., semiconductor laser diodes. Further, although the general discussion of the exemplary structures of the invention discussed herein is directed toward inorganic LED based light sources, it should be understood that the LED chip may be replaced by another radiation source unless otherwise noted and that any reference to semiconductor, semiconductor LED, or LED chip is merely representative of any appropriate radiation source, including, but not limited to, organic light emitting diodes.

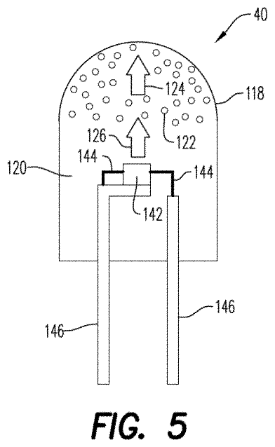

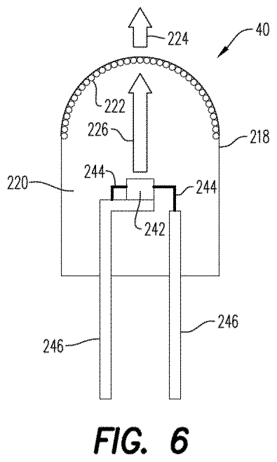

In lighting device 40, a layer 22 including a blend of an encapsulant material 20 and the small particle size red phosphor of the present disclosure overlays at least one LED chip 42 disposed within the cavity. It is noted that in some embodiments, such as FIG. 4, the overlaid layer 22 may be in direct contact with the at least one LED chip 42, while in some embodiments, such as FIGS. 5 and 6, the overlaid layer 122, 222, may not be in direct contact with the at least one LED chip 42. The layer 22, 122, 222 may be disposed within the cavity 10. The layer 22 is radiationally coupled to the chip 42. The layer 22 may be deposited on the LED 42 by any appropriate method known in the art. For example, a water-based suspension of the phosphor(s) may be formed, and applied as a phosphor layer to the LED surface. In one such method, a silicone slurry in which the phosphor particles are randomly suspended is placed around the LED. This method is merely exemplary of possible positions of the layer 22 and the LED 42. Thus, the layer 22 may be coated over or directly on the light emitting surface of the LED chip 42 by coating and drying a phosphor suspension over the LED chip 42. In the case of a silicone-based suspension, the suspension is cured at an appropriate temperature.

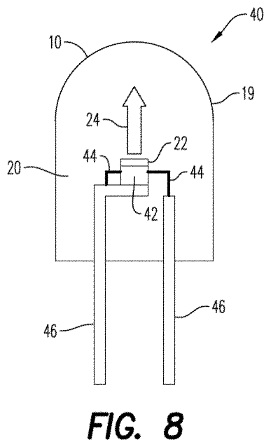

In one or more embodiments, the LED chip 42 may be covered, at least partially, by an envelope 18 or lens 19 (FIG. 8), which encloses the LED chip 42, and an encapsulant material 20. Both the envelope 18 and the encapsulant material 20 should be transparent to allow emitted light to be transmitted through those elements. The envelope 18 may be, for example, glass or plastic. The LED chip 42 may be enclosed by the encapsulant material 20. The encapsulant material 20 may be at least one of: a low temperature glass, a thermoplastic, a thermoset polymer, and a resin as known in the art, for example, a silicone resin or an epoxy resin. In an alternate embodiment, the lighting device 40 may only comprise the encapsulant material 20 without the envelope 18 to form the cavity 10. It is noted that the same type of encapsulant material may be used for both the blended layer 22, 122, 222 and the encapsulant 20 forming the cavity 10.

Various structures of the lighting device 40 are known in the art. For example, in some embodiments, the small particle size red phosphor of the present disclosure 22 (that, in one embodiment, is disposed on a surface of the chip 42 in FIG. 4) may alternatively be interspersed within the encapsulant material 120, as shown in FIG. 5 as 122, instead of being disposed directly on the LED chip 42. Corresponding numbers from FIGS. 4-6 (e.g., 22 in FIG. 4 and 122 in FIG. 5) relate to corresponding structures in each of the figures, unless otherwise stated. The small particle size red phosphor of the present disclosure 122 (in the form of a powder) may be interspersed within a single region of the encapsulant material 120 or throughout the entire volume of the encapsulant material. Radiation, not shown in FIG. 4, but shown as 126 and 226 in FIGS. 5 and 6, respectively, emitted by the LED chip mixes with the light emitted by the small particle size red phosphor of the present disclosure 22/122/222 to produce desired emission (indicated by arrow 24 in FIG. 4, 124 in FIG. 5, and 224 in FIG. 6). If the small particle size red phosphor material 122 is to be interspersed within the material of encapsulant 120, then a small particle size red phosphor powder of the present disclosure having may be added to a polymer or silicone precursor, and then the mixture may be cured to solidify the polymer or silicone material. Examples of polymer precursors include thermoplastic or thermoset polymers or a resin, for example epoxy resin. Other known phosphor interspersion methods may also be used, such as transfer loading.

In some other embodiments, the small particle size red phosphor of the present disclosure may be coated onto a surface of the envelope 218, as shown in FIG. 6. The red phosphor of the present disclosure having a small particle size 222 is preferably coated on the inside surface of the envelope 218, although the small particle size red phosphor of the present disclosure may be coated on the outside surface of the envelope 218, if desired. Small particle size red phosphor of the present disclosure may be coated on the entire surface of the envelope or only a top portion of the surface of the envelope. The radiation emitted by the LED chip 42 mixes with the light emitted by the small particle size red phosphor of the present disclosure, and the mixed light appears as white light 224. Of course, the structures of FIGS. 4-6 may be combined and the small particle size red phosphor of the present disclosure may be located in any two or all three locations or in any other suitable location, such as separately from the shell or integrated into the LED. Further, different phosphor blends may be used in different parts of the structure.

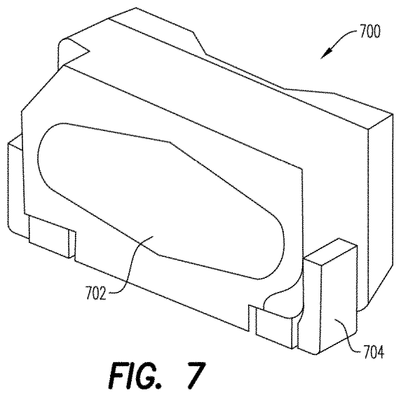

Another structure (particularly for backlight applications) is a surface mounted device (“SMD”) type light emitting diode 700 e.g., as shown in FIG. 7. This SMD is a “side-emitting type” and has a light-emitting window 702 on a protruding portion of a light guiding member 704. An SMD package may comprise an LED chip as described herein, and a small particle size red phosphor of the present disclosure. Other backlight devices include, but are not limited to, TVs, computers, and hand-held devices such as smartphones and tablet computers.

In any of the above structures, the lighting device 40 may also include a plurality of particles (not shown) to scatter or diffuse the emitted light. These scattering particles are generally embedded in the encapsulant 20/120/220. The scattering particles may include, for example, particles made from alumina (Al₂O₃) or titanium dioxide (TiO₂). The scattering particles may effectively scatter the light emitted from the LED chip 42, preferably with a negligible amount of absorption.

While only certain features of the invention have been illustrated and described herein, many modifications and changes will occur to those skilled in the art. It is, therefore, to be understood that the appended claims are intended to cover all such modifications and changes as fall within the true spirit of the invention.

The invention of the present disclosure may be defined more fully by reference to the following claims:

1. An LED lighting apparatus comprising:
an enclosure defining a cavity within the enclosure, the cavity comprising a depth dimension;
at least one LED chip;
a layer comprising a blend of an encapsulant material and phosphor composition, the layer overlaying the at least one LED chip and disposed within the cavity;
the phosphor composition comprising a yellow-green phosphor and a Mn⁴⁺ doped complex fluoride phosphor of formula I,
Aₓ[MF_{y}]:Mn⁴⁺ (I)
where A is Li, Na, K, Rb, Cs, NR₄ or a combination thereof; M is Si, Ge, Sn, Ti, Zr, Al, Ga, In, Sc, Hf, Y, La, Nb, Ta, Bi, Gd, or a combination thereof; R is H, lower alkyl, or a combination thereof; x is the absolute value of the charge of the [MF_{y}] ion; and y is 5, 6, or 7;
wherein the Mn⁴⁺ doped complex fluoride phosphor of formula I comprises a d50 particle size of from about 1 micrometers to about 10 micrometers, and
the LED lighting apparatus, when activated, emits visible light comprising a correlated color temperature (CCT) of from about 2500 K to about 3700 K.

2. The LED lighting apparatus of claim 1, wherein the CCT is from about 2500 K to about 3500 K.

3. The LED lighting apparatus of claim 1, wherein the depth dimension is from about 200 microns to about 800 microns.

4. The LED lighting apparatus of claim 1, wherein the encapsulant material is at least one of: a low temperature glass, a thermoplastic, a thermoset polymer, and a resin.

5. The LED lighting apparatus of claim 4, wherein the resin is one of a silicone resin or an epoxy resin.

6. The LED lighting apparatus of claim 1, wherein the LED chip and the layer are partially covered by the enclosure.

7. The LED lighting apparatus of claim 1, wherein the encapsulant material forms the enclosure.

8. The LED lighting apparatus of claim 1, wherein the LED chip and encapsulant are at least partially covered by a lens.

9. The LED lighting apparatus of claim 1, wherein the layer comprising the blend of encapsulant material and phosphor composition is radiationally coupled to the LED chip.

10. A method comprising:
receiving phosphor pre-cursor for a phosphor composition comprising a yellow-green phosphor and a Mn⁴⁺ doped complex fluoride phosphor of formula I,
Aₓ[Mf_{y}]:Mn⁴⁺ (I)
where A is Li, Na, K, Rb, Cs, NR₄ or a combination thereof; M is Si, Ge, Sn, Ti, Zr, Al, Ga, In, Sc, Hf, Y, La, Nb, Ta, Bi, Gd, or a combination thereof; R is H, lower alkyl, or a combination thereof; x is the absolute value of the charge of the [MF_{y}] ion; and y is 5, 6, or 7;
generating the phosphor pre-cursor for the phosphor composition of formula I having a d50 particle size of from about 1 micrometer to about 10 micrometers;
generating the phosphor composition of formula I from the generated phosphor pre-cursor having the d50 particle size of from about 1 micrometer to about 10 micrometers;
constructing an LED lighting apparatus with the generated phosphor composition; and
in a case that the constructed LED lighting apparatus is activated, emitting visible light comprising a CCT from about 2500K to about 3700K.

11. The method of claim 10, wherein constructing the LED lighting apparatus further comprises:
providing an enclosure defining a cavity;
generating a layer comprising a blend of an encapsulant material and the generated phosphor composition;
overlaying the generated layer over the at least one LED chip of the LED lighting apparatus, wherein the at least one LED chip is disposed within the cavity.

12. The method of claim 11, wherein the cavity has a depth dimension is from about 200 microns to about 800 microns.

13. The method of claim 11, wherein the layer is radiationally coupled to the at least one LED chip.

14. The method of claim 10, wherein generating the phosphor pre-cursor for the phosphor composition of formula I having the d50 particle size of from about 1 micrometer to about 10 micrometers further comprises:
milling the phosphor pre-cursor to the d50 particle size of from about 1 micrometer to about 10 micrometers.

15. The method of claim 14, further comprising:
determining the milled phosphor pre-cursor has the d50 particle size of from about 1 micrometer to about 10 micrometers via scanning electron microscopy (SEM).

16. The method of claim 10, wherein the CCT is from about 2500 K to about 3500 K.

17. The method of claim 10, wherein the encapsulant material is at least one of: a low temperature glass, a thermoplastic, a thermoset polymer, and a resin.
